(19) United States
(12) Patent Application Publication
(10) Pub. No.: US 2016/0168689 A1
(43) Pub. Date: Jun. 16, 2016

(54) SYSTEMS AND METHODS FOR FORMATION OF EXTENDED LENGTH NANOSTRUCTURES ON NANOFILAMENT SUPPORT

(71) Applicant: Nanocomp Technologies, Inc., Merrimack, NH (US)

(72) Inventor: Mark A. Banash, Bedford, NH (US)

(21) Appl. No.: 14/567,259

(22) Filed: Dec. 11, 2014

(51) Int. Cl. C23C 16/02; C23C 16/26; C23C 16/32

(52) U.S. Cl. CPC C23C 16/0209; C23C 16/32; C23C 16/26

(57) ABSTRACT

A system for synthesis of extended length nanostructures comprising a nanofilament acting as a support on which an extended length nanostructure may be formed; and furnaces through which the nanofilament is directed in which a source material is deposited on the nanofilament, decomposed to form a layer of precursor coating the nanofilament, and further heated to rearrange the atomic structure of the surface layer to form the nanostructure. A system comprising an array of nanofilaments; and zones within which a layer of precursor material is applied to each nanofilament, and heated to rearrange the atomic structure of the corresponding precursor surface layers to form the plurality of nanostructures. A method for synthesizing a plurality of extended length nanostructures comprising depositing a source material onto a nanofilament; decomposing the source material to form a layer of nanostructure precursor; and rearranging the atomic structure of the nanostructure precursor layer.

### TECHNICAL FIELD

The present invention relates to nano structures, and more particularly, extended length nanostructures formed on a nanofilament support.

### BACKGROUND

Carbon nanotubes can be manufactured utilizing a number of different processes. One approach employs chemical vapor deposition (CVD), in which nanotubes may be synthesized using a carbonaceous gas in the presence of catalyst particles, either free-floating or on a substrate, at high temperatures. In such an approach, the carbon source decomposes into its carbon constituent, and the carbon atoms are deposited onto the surface of the catalyst particle where they ultimately collect on the surface of the particle in an organized manner to form the basis of the nanotube. Growth will typically continue as long as the carbon source is provided in the presence of the catalyst particle. Resulting nanotubes may have lengths from a few hundred nanometers to several millimeters.

Larger nanomaterials, such as sheets and yarns, may be manufactured from a plurality of these relatively small nanotubes. Depending on the particular construction of a given nanomaterial, the nanotubes may be held together by frictional forces at various inter-tube junctions, or in some cases, by a binder material or substrate. Typically, the macroscale strength of such materials is dictated by the strength of these frictional forces, or by the structural integrity of any binder that may be present. The presence of these inter-tube junctions and binder material may also affect macroscale conductivity of the material, as each may introduce resistance to current passing through the material. Of course, variances in strength and conductivity of the individual nanotubes themselves may further affect corresponding macroscale properties in the resulting nanomaterial. On the other hand, nanomaterials formed from longer, continuous nanostructures may exhibit greater mechanical strength, electrical conductivity, and thermal conductivity.

### SUMMARY OF THE INVENTION

The present disclosure is directed to a system for synthesis of extended length nanostructures. The system may comprise a nanofilament acting as a support on which an extended length nanostructure may be formed. The nanofilament may be directed through a first furnace within which: a) a source material for forming a nanostructure is deposited circumferentially around the nanofilament, and b) the source material is decomposed into its constituent atoms to form a surface layer of nanostructure precursor coating the nanofilament. The precursor-coated nanofilament may subsequently be directed through a second furnace within which it is exposed to a temperature range higher than that in the first furnace to rearrange the atomic structure of the surface layer to form the nanostructure.

In various embodiments, the nanofilament may include a material made from one of magnesium oxide, zinc oxide, indium tin oxide, boron nitride, and a high temperature polymer, and may have a diameter up to 100 nanometers.

The first furnace, in an embodiment, may be configured to heat the nanofilament to a first temperature range sufficient to decompose the source material into the nanostructure precursor upon contact with the heated nanofilament. The nanofilament may be heated between 500° C. and 1500° C. in an embodiment. The source material may include one of a purely carbonaceous material, an oxygen-containing carbonaceous material, a sulfur-containing carbonaceous material, a hydrocarbon compound, and a boron-containing compound.

In an embodiment, the temperature range of the second furnace is between 1500° C. and 3000° C. The temperature range of the second furnace, in various embodiments, may be sufficient to remove secondary materials from the coating and/or decompose the nanofilament on which the nanostructure is formed.

The nanostructure may be synthesized circumferentially about the nanofilament, and may approximate the shape and size of the nanofilament. In an embodiment, the formed nanostructure may be free of residual catalyst.

The system may further include a nanofilament distributor from which the nanofilament may be directed. In an embodiment, the nanofilament distributor may include a nanofilament formation device for synthesizing the nanofilament from a nanofilament precursor material, perhaps via on of an electrospinning process or a pyroelectrodynamic shooting process. The system may also include a collector downstream of the second furnace for collecting the nanostructure.

The system may be modified for synthesis of a plurality of extended length nanostructures. An array of nanofilaments may be provided for serving as supports on which a plurality of nanostructures may be formed. The system may comprise a first zone through which the nanofilaments are directed and within which a layer of precursor material from which a nanostructure may be formed is applied to a surface of each nanofilament. The system may further comprise a second zone, situated downstream from the first zone, within which the nanofilaments are exposed to a temperature range to rearrange the atomic structure of the corresponding precursor surface layers thereon to form the plurality of nanostructures. The plurality of nanostructures may be formed having substantially uniform diameters.

This system may further include a collector downstream of the second zone for simultaneously collecting at least two of the plurality of nanostructures. In an embodiment, the collector may be configured to form a twisted yarn from the nanostructures during collection.

The present disclosure is also directed to a method for synthesizing a plurality of extended length nanostructures. The method may include the steps of depositing, onto a nanofilament support, a source material for forming a nanostructure; decomposing, at a first temperature range, the source material to form a surface layer of nanostructure precursor on the nanofilament; and rearranging, at a second temperature range higher than the first temperature range, atomic structure of the nanostructure precursor surface layer on the nanofilament to form the nanostructure.

### BRIEF DESCRIPTION OF DRAWINGS

For a more complete understanding of this disclosure, reference is now made to the following description, taken in conjunction with the accompanying drawings, in which:

FIG. 1 illustrates a schematic view of a system for synthesis of extended length nanostructures, in accordance with one embodiment of the present disclosure;

FIG. 2 shows a schematic view of a nanofilament distributor, in accordance with one embodiment of the present disclosure;

FIG. 3 depicts a schematic view of a first furnace of the system of FIG. 1, in accordance with one embodiment of the present disclosure;

FIG. 4 provides a schematic view of a second furnace of the system of FIG. 1, in accordance with one embodiment of the present disclosure;

FIG. 5A illustrates a comparison of normalized Raman intensity in a nanostructure precursor material before and after exposure to graphitization conditions;

FIG. 5B illustrates an elemental comparison of a nanostructure precursor material before and after exposure to graphitization conditions;

FIG. 5C illustrates a representative Scanning Emission Microscopy (SEM) image of a graphitized nanostructure precursor material as sampled by x-ray analysis;

FIG. 6A depicts a schematic view of a system for synthesis of a plurality of extended length nanostructures, in accordance with one embodiment of the present disclosure;

FIG. 6B depicts a schematic view of a system for synthesis of a plurality of extended length nanostructures, in accordance with another embodiment of the present disclosure;

FIG. 6C depicts a schematic view of a system for synthesis of a plurality of extended length nanostructures, in accordance with yet another embodiment of the present disclosure; and

FIG. 6D depicts a schematic view of a system for synthesis of a plurality of extended length nanostructures, in accordance with still another embodiment of the present disclosure.

### DESCRIPTION OF SPECIFIC EMBODIMENTS

Embodiments of the present disclosure generally provide systems 100, 600 for continuous synthesis of substantially catalyst-free, extended length nanostructures on a nanofilament support, and a method of manufacturing the same.

### System 100

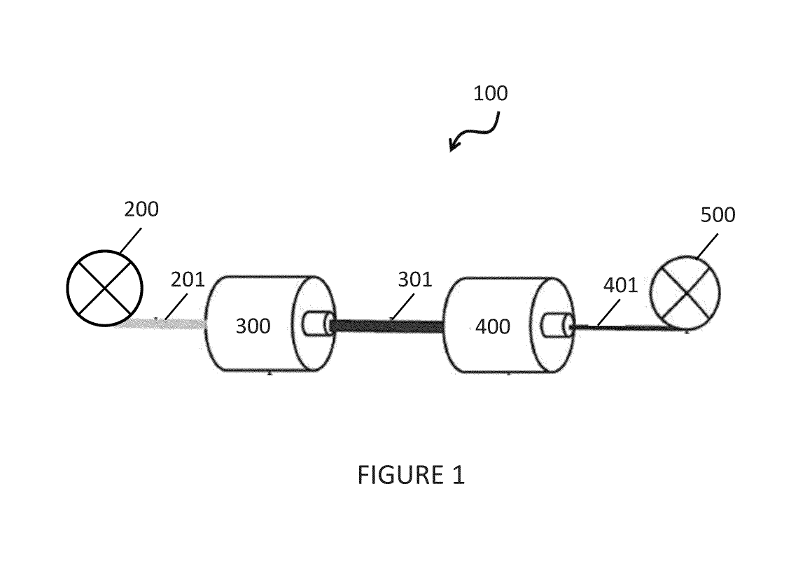

FIGS. 1-4 illustrate representative configurations of system 100 and components thereof. It should be understood that the components of system 100 shown in FIGS. 1-4 are for illustrative purposes only, and that any other suitable components or subcomponents may be used in conjunction with or in lieu of the components comprising system 100 described herein.

Embodiments of system 100 may be used in connection with the continuous synthesis of extended length nanostructures on a nanofilament support, amongst other possible uses.

FIG. 1 depicts an embodiment of system 100. System 100 may generally include a nanofilament distributor 200, a continuous nanofilament 201 on which a nanostructure can be formed, a first furnace 300, a second furnace 400, and a collector 500, all of which are described in more detail herein.

System 100 may include a nanofilament distributor 200 from which nanofilament 201 can be dispensed in a continuous manner. Distributor 201, in one embodiment, may include a spool or any other mechanism suitable for dispensing a stored quantity of previously-formed nanofilament 201.

In another embodiment, distributor 200 may include a drag mechanism for controllably dispensing and applying tension to nanofilament 201 as it is continuously directed through system 100. Nanofilament 201 may be tensioned for a variety of reasons. For example, in an embodiment, tension may straighten nanofilament 201 as it is directed through system 100, and thereby provide a substantially straight support surface on which a nanostructure may be grown. In another embodiment, tension may serve to keep nanofilament 201 from curling, shrinking, or otherwise deforming as it is exposed to various temperature throughout system 100. Tension may further serve to counteract any tendency of nanofilament 201 to sag under the weight of a nanostructure being formed thereon. Still further, tension in nanofilament 201 may serve to maintain the shape and integrity of a nanostructure growing thereon by resisting any tendency of the nanostructure itself to deform throughout the synthesis process. In an embodiment, distributor 200 may apply approximately 10 N of tension on nanofilament 201 as it is continuously directed through system 100.

Nanofilament 201 for use in connection with system 100 of the present disclosure may have a diameter on the nano-scale. In an embodiment, nanofilament 201 may have a diameter of about 100 nm or less depending on the particular application. In one such embodiment, nanofilament 201 may have a diameter of about 10 nm or less. Nanofilament 201 may also be provided with any suitable cross-sectional shape. In one embodiment, nanofilament 201 may be substantially cylindrical in shape. To the extent desired, the eccentricity of such an embodiment may be limited to about 0.1 to minimize substantial deviations from circularity. It should be recognized that nanostructure 401 may approximate the dimensions and shape of nanofilament 201, and that the above-referenced examples are merely illustrative examples that may be suitable for supporting the growth of a tubular nanostructure 401. To that end, nanofilament 201 may be provided with any geometric cross-sectional shape.

Nanofilament 201 may be formed from any material suitable for supporting growth of a nanostructure thereon as it is directed through system 100. In some embodiments, nanofilament 201 may be formed from inorganic materials, such as magnesium oxide, zinc oxide, indium tin oxide, boron nitride, amongst others. Magnesium oxide, a primary ingredient in antacids, can be a particularly inexpensive option. In other embodiments, nanofilament 201 may be formed from organic materials like high temperature polymers, such as poly(indanes), poly(p-phenylene-2,6-benzobisoxazole) (PBO), polybenzimidazole (PBI), and poly {2,6-diimidazo[4,5-b:4′,5′-e]-pyridinylene-1,4(2,5-dihydroxy)phenylene} (PIPD). Each of these decompose at temperatures above 600° C., making them well suited for supporting nanostructure precursor 301 in furnace 300, and subsequently being decomposed within furnace 400, as later described. In yet another embodiment, nanofilament 201 may be formed from a ceramic material. To the extent desired, nanofilament 201 may include strong, heat resistant materials capable of maintaining structural integrity under tension and at high temperatures.

Nanofilament 201 may be synthesized using an electrospinning process, a pyroelectrodynamic shooting process, or any other suitable process known in the art. For example, a ceramic nanofilament 201 may be formed from a ceramic precursor solution via an electrospinning process. In such an approach, the solution may, in an embodiment, include a solvent and one or more ceramic-forming compounds like metal salts, organometallic compounds, and inorganic powders. To the extent desired, the solution may also include one or more adjuvant such as, without limitation, viscosity modifiers, surfactants or other solubility aids, and polymers. The solvent may be aqueous and have a pH range adjusted for maximum solubility of the ceramic-forming compound. To the extent desired, the solvent may be subsequently removed from the nanofilament after it has been formed using heat, centrifugal force, or any other suitable method. Additionally, the formed nanofilament 201 may be further subjected to a calcination process to remove contaminates. The formed nanofilament may also be tensioned or stretched to adjust its diameter if necessary.

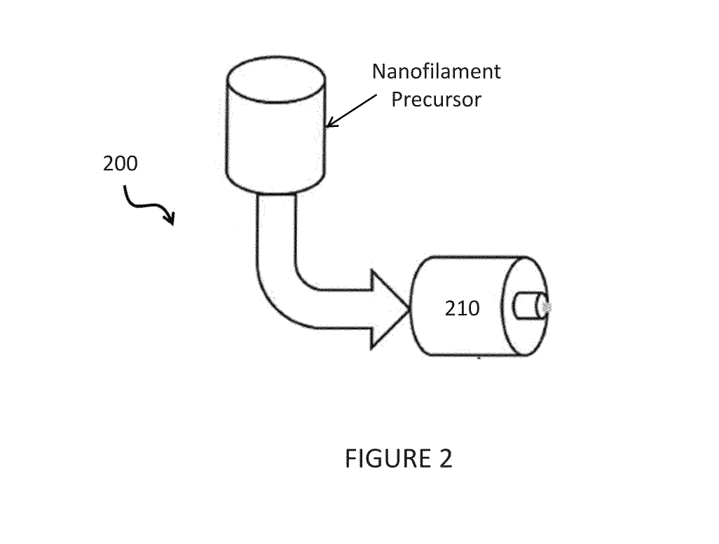

Referring now to FIG. 2, in various embodiments, nanofilament 201 may be formed within and dispensed continuously from nanofilament distributor 200. For example, nanofilament distributor 200 may include a nanofilament formation device 210 for synthesizing nanofilament 201 from a precursor material utilizing one of the above-referenced processes, or any other suitable process for forming nanofilament 201. In an embodiment, nanofilament formation device 210 may utilize electrospinning to continuously form nanofilament 201 for continuous distribution.

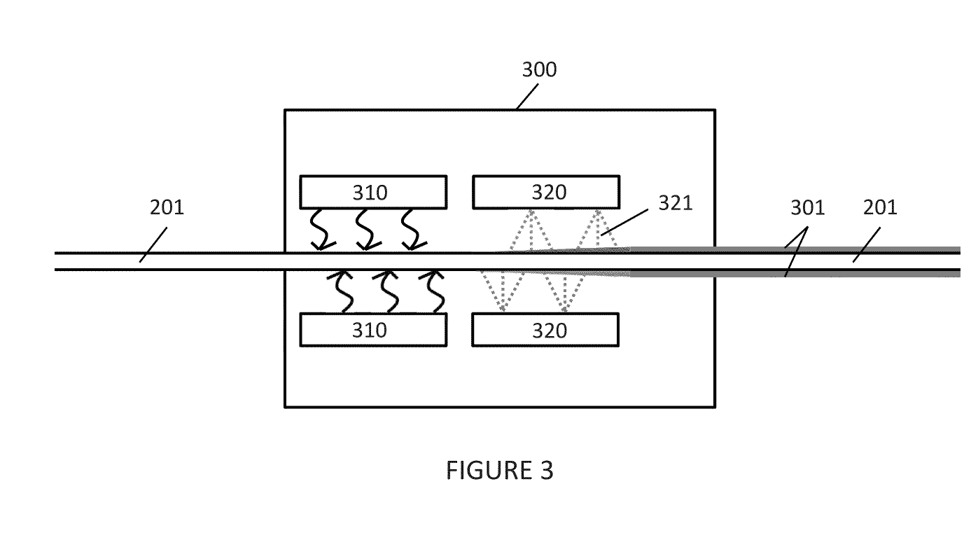

Referring now to FIG. 3, system 100 may also include a furnace 300 through which nanofilament 201 may be directed for the next stage of nanostructure formation. In this stage, nanofilament 201, in one embodiment, may be coated with a surface layer of a nanostructure precursor 301 from which nanostructure 401 may ultimately be formed.

Furnace 300, in an embodiment, may include a heater 310. Heater 310 may be configured to heat nanofilament 201 to a temperature range T₁ necessary to subsequently decompose a source material 321 into its constituent elements upon contact with the heated nanofilament 201 to form a layer of nanostructure precursor 301 on the surface of nanofilament 201 from which a nanostructure may ultimately be formed. In an embodiment, temperature range T₁ may be from about 500° C. to about 1500° C. Heater 310 may utilize any suitable form of heating to heat nanofilament 201 including, but not limited to, radiative heating, conductive heating, or RF heating. In an embodiment, heater 310 may be positioned in such a manner as to direct heat circumferentially about nanofilament 201 and in a substantially uniform fashion as nanofilament 201 is directed therethrough.

It should be appreciated that the duration for which nanofilament 201 is heated within furnace 300 may vary depending on a number of factors such as the desired temperature to which nanofilament 201 is to be heated, the composition of nanofilament 201, and the desired thickness of nanostructure precursor layer 301 to be formed thereon.

Furnace 300 may further include a dispenser 320 for dispensing source material 321 from which nanostructure 401 may ultimately be formed. In an embodiment, dispenser 320 may include one or more ports, nozzles, or other suitable mechanisms for dispensing source material 321 onto the surface of nanofilament 201. Dispenser 320 may be configured to deposit source material 321 onto nanofilament 201 to form a substantially uniform coating of source material 321 thereon. For example, in one embodiment, dispenser 320 may be positioned in such a manner as to direct source material 321 circumferentially about nanofilament 201. It should be appreciated that even though dispenser 320 is described as dispensing source material 321 onto nanofilament 201, nanofilament 201 may alternatively be immersed within bath of source material 321, or coated in any other suitable manner known in the art. In various embodiments, source material 321 may be provided to furnace 300 in any suitable state (gaseous, nebulized mist, liquid, etc.) for subsequent deposition onto nanofilament 201. Further, furnace 300 may, in an embodiment, be provided with an inert atmosphere to minimize oxidation at this stage of nanostructure formation.

Source material 321, in various embodiments, may include any carbonaceous material, including purely carbonaceous material, as well as those including oxygen and sulfur atoms. Some examples include without limitation alkanes, alkenes, alkynes, and aromatics as straight carbon sources. Some oxygen-containing carbonaceous species may include alcohols, esters, ethers, ketones, and aldehydes. Sulfur analogs of the oxygen-containing molecules, such as a thiol inside of an alcohol, as well as species containing both oxygen and sulfur, such as sulfolane, may be used as source material 321. In another embodiment, source material 321 may include a compound comprised of carbon or any other suitable element from which a nanostructure may ultimately be synthesized. For example, source material 321 may include a hydrocarbon compound capable of being decomposed into its constituent atoms, hydrogen and carbon, when heated to within temperature range T₁. The carbon atoms, in an embodiment, may collect on the surface of nanofilament 201 to form layer of substantially solid carbon (i.e., nanostructure precursor 301), and the hydrogen atoms may be dispersed. The carbon atoms may accumulate on nanofilament 201 in a fairly unorganized fashion such that the resulting layer nanostructure precursor 301 is formed with a relatively disordered atomic structure. Even though source material 321 is described for illustrative purposes as a carbon-containing compound, it should be recognized that source material 321 may also include any suitable non-carbonaceous compound, such as a boron-containing compound, from which a corresponding nanostructure 401 may be formed in accordance with embodiments of the present disclosure.

Nanostructure precursor 301 may continue to accumulate on a given portion of nanofilament 201 so long as source material 321 is provided and temperatures remain sufficient to decompose source material 321 thereon. As such, the thickness of nanostructure precursor layer 301 may correspond with the speed at which nanofilament 201 is directed through furnace 300. For example, at high speeds, only a single layer of nanostructure precursor atoms 301 might accumulate on a given portion of nanofilament 201. Conversely, at low speeds, multiple layers of these atoms 301 may accrue. It should be recognized that the thickness of this overall layer of nanostructure precursor 301 may be determinative of whether its atomic structure is subsequently reorganized to form a single-walled nanostructure 401 or a multi-walled nanostructure, as later described.

Furnace 300, in accordance with one embodiment of the present disclosure, may be designed to generate heat at this stage of nanostructure formation in an energy efficient manner. For example, because only nanofilament 201 need be heated, and not a larger reactor volume as may be the case with CVD processes, furnace 300 may be configured to minimize energy consumption by concentrating heating within the relatively small area immediately surrounding nanofilament 201. Further, furnace 300 may be designed to promote efficient chemical reactions. For example, because this stage of nanostructure formation occurs in a localized area—that is, on the portion of nanofilament 201 being treated at any given time—furnace 300 may be configured to concentrate reactions within this relatively small area. This may serve to minimize the number of side reactions competing for source carbon relative to those occurring in CVD processes, in which large reactors are required for sophisticated control of catalyst particle size, reaction temperatures, and reactant mixing. These factors, amongst others, may enable furnace 300 to be designed with a relatively small diameter—in some embodiments, less than one inch. It should be recognized; however, that the diameter of furnace 300 may vary depending on the application.

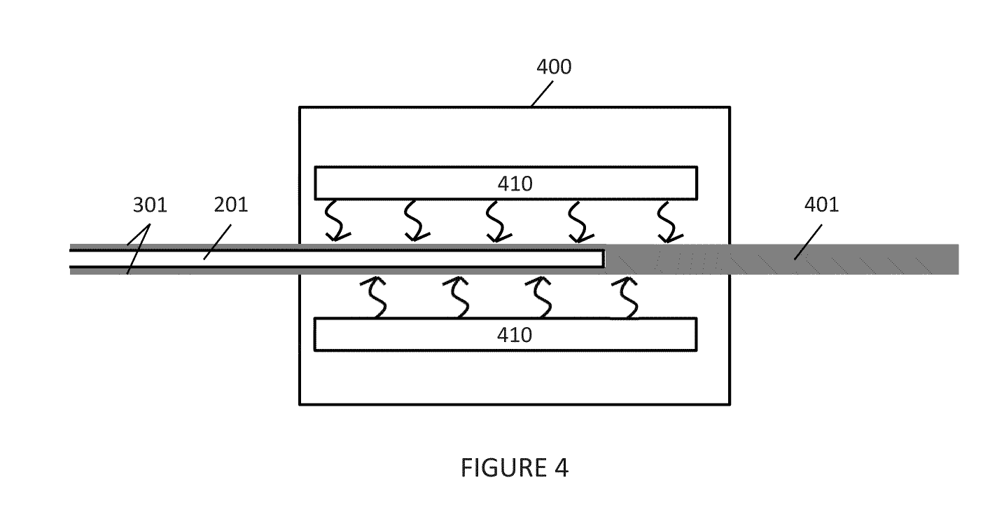

Referring now to FIG. 4, system 100 may further include a furnace 400 through which the nanostructure precursor-coated nanofilament 201 may be directed for the next stage of nanostructure formation.

Furnace 400, in an embodiment, may include a heater 410. Heater 410 may be configured to generate a temperature range T₂ suitable to rearrange the atomic structure of the nanostructure precursor layer 301 to form nanostructure 401. In an embodiment, temperature range T₂ may be from about 1500° C. to about 3000° C. In one such embodiment, furnace 400 may be heated to about 2000° C. Heater 410 may utilize any suitable form of heating to heat nanostructure precursor layer 301 including, but not limited to, radiative heating, conductive heating, or RF heating. In an embodiment, heater 410 may be positioned in such a manner as to direct heat circumferentially about the nanostructure precursor-coated nanofilament 201 and in a substantially uniform fashion as the nanostructure precursor-coated nanofilament 201 is directed thereby. Furnace 400, in an embodiment, may also be provided with an inert atmosphere to minimize oxidation at this stage of nanostructure formation.

At such temperatures, the relatively disordered atomic structure of nanostructure precursor layer 301 may be rearranged to form a more ordered structure resembling conventional nanotube structures, i.e., nanostructure 401. As previously noted, the thickness of nanostructure precursor layer 301 may influence the manner in which its atomic structure is reorganized. For example, a substantially single layer of nanostructure precursor 301 atoms may be rearranged to form a single-walled nanostructure 401. Conversely, in the case of a thicker coating of nanostructure precursor 301, various sub-layers of nanostructure precursor atoms 301 may be reorganized to form the concentric walls characteristic of a multi-walled nanostructure 401. Nanostructure 401 may have a slightly smaller diameter than that of nanostructure precursor layer 301 due to compaction during the rearrangement of atomic structure thereof within furnace 400.

The temperatures at which this atomic reorganization may occur can be higher than those typically associated with the growth of nanotubes by chemical vapor deposition (CVD). In one experiment, carbon tubules generated by the decomposition of methane onto MgO particles at typical CNT synthesis temperatures (e.g., approximately 1200° C.) exhibited very disordered atomic structures. However, heating those tubules at approximately 1600° C. to approximately 1800° C. resulted in the formation of nanotubes with ordered structure. This was confirmed by Raman spectroscopic and TEM analyses, both of which are sensitive to the disorder-order transition described herein. In some embodiments, particularly those in which nanostructure precursor 301 is carbon-based, graphitization temperatures may produce the most stable and ordered nanostructures 401.

Heating within temperature range T₂ may further serve to remove secondary materials from the developing nanostructure 401. For example, in an embodiment, such heating may remove non-carbonaceous materials like oxygen, magnesium, iron and potassium from a predominately carbon-containing precursor layer 301. Removal of these secondary materials may increase the purity of ultimately-formed carbon nanostructure 401. One having ordinary skill in the art will recognize appropriate combinations of temperature and residence time suitable for removing a given substance from surface layer 301.

Furnace 400, in an embodiment, may be further configured to heat the coated nanofilament to a temperature sufficient to decompose and remove nanofilament 201 supporting nanostructure 401, so as to leave only nanostructure 401 for subsequent harvesting. Depending on the application, additional heating may not be required to do so beyond that necessary to form nanostructure 401. However, if necessary, furnace 400 may be configured to further heat nanofilament 201 to remove it after nanostructure 401 is formed. In one such embodiment, furnace 400 may be configured to continue exposing nanofilament 201 to temperature range T₂ for a period of time after nanostructure 401 is formed. This additional residence time may allow nanofilament 201 to reach temperatures required for its decomposition and removal from nanostructure 401. In another such embodiment, furnace 400 may be configured to provide higher temperatures than those necessary for forming nanostructure 401. To that end, in an embodiment, furnace 400 may include a second heater (not shown) or other suitable mechanism downstream of heater 410 for generating temperatures sufficient to decompose and remove nanofilament 201. In an embodiment, the second heater may be positioned such that nanofilament 201 is exposed to these higher temperatures only after nanostructure 401 is either formed thereon, or at least developed to a point where removal of nanofilament 201 does not compromise the formation of nanostructure 401. It should be recognized that such a configuration could also be useful for further removing any impurities that may be present in nanostructure 401. Of course, regardless of the application, care should be taken to avoid reaching temperatures and residence times that may negatively affect nanostructure 401.

It should be appreciated that duration for which the nanostructure precursor-coated nanofilament 201 is heated within furnace 400 may vary depending on a number of factors such as the composition and thickness of nanostructure precursor layer 301, and the composition of nanofilament 201 if it is to be decomposed therein.

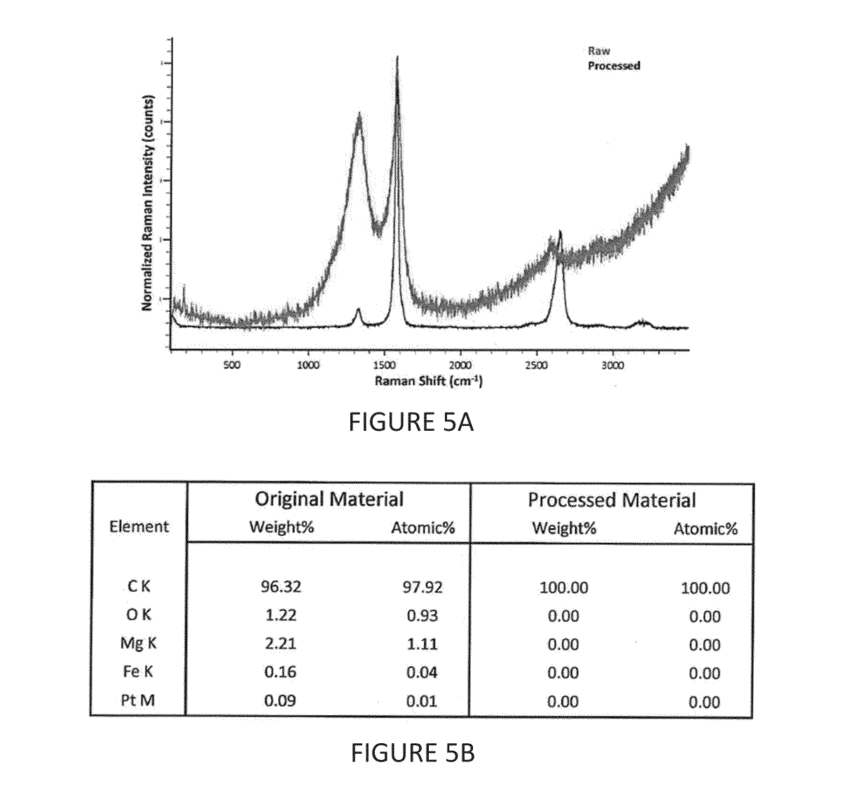

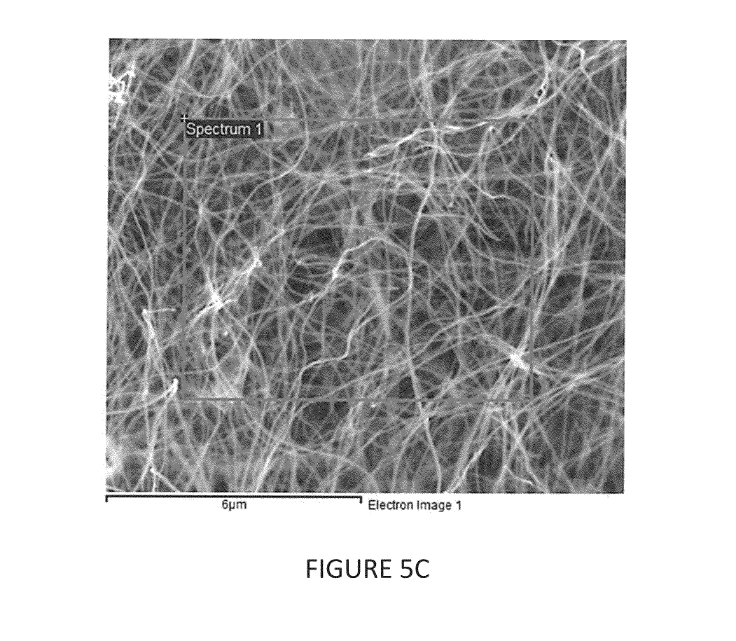

Referring now to FIGS. 5A-5C, an experiment was conducted to demonstrate the effects, both structurally and compositionally, of exposing a carbonaceous precursor material 301 formed on a sacrificial magnesium oxide nanofilament 201 in accordance with the present disclosure to conditions similar to those of furnace 400. FIG. 5A provides a comparison of normalized Raman intensity in the raw precursor material 301 and the resulting processed carbon nanomaterial 401 as a measure of graphitization that took place as a result of exposure. The decrease in the D band around 1300 cm⁻¹ and the narrow G band around 1580 cm⁻¹ demonstrate an increase in structured nanocarbon. FIG. 5B provides an elemental comparison of the raw material and the graphitized material that demonstrates how the graphitization treatment eliminated of all other elements except carbon from the material. FIG. 5C provides a representative Scanning Emission Microscopy (SEM) image of the graphitized nanomaterial sampled by x-ray analysis revealing the resulting nanotube structure.

Referring back to FIG. 1, system 100 may further include a collector 500 for collecting nanostructure 401 after it is formed. In an embodiment, collector 500 may include a spool or any other mechanism suitable for these purposes.

Collector 500 may be further configured to continuously pull nanofilament 201 through the various stages of system 100 at a substantially constant speed. Depending on the application, embodiments of the present disclosure allow for speeds approaching 300 miles per hour, providing for a high throughput of nanostructure formation. It should be appreciated that system 100 may be adapted to accommodate any differences in residence time required at various stages of system 100 while maintaining this constant speed. For example, in one embodiment, nanofilament 201 may be directed along a circuitous route within a given stage to increase residence time, or alternatively, be directed along a relatively straight path to decrease residence time therein. In another embodiment, the physical length of various stages may be adjusted to provide an appropriate residence time within each, while continuing to direct nanofilament 201 through system 100 at a substantially constant speed. Although designed to provide nanofilament 201 with substantially constant speed, it should be appreciated that the speed of nanofilament 201 through system 100 can vary, depending on the application.

Unlike other nanostructure synthesis methods, which may produce nanostructures containing the catalyst particle on which each was formed, embodiments of the present disclosure provide for the formation of hollow nanostructures that are free of residual catalyst. Additionally, various aspects of system 100 provide for the precise control of factors affecting the shape and size of nanostructures 401 synthesized therein. For example, the ability to concentrate heating and growth within a small, controlled area around nanofilament 201 provides for the synthesis of extended length nanostructures having substantially uniform properties along their entire lengths. Similarly, this aspect may provide for repeatable and predictable growth of a plurality of substantially uniform nanostructures in series. Likewise, because nanostructure 401 may approximate the shape and size of nanofilament 201, careful manufacture of nanofilament 201 may provide similar benefits. Still further, embodiments of the present disclosure provide for the manufacture of nanostructures of theoretically unlimited length so long as a heated nanotube filament 201 and source material 321 are continuously provided to successive portions of nanofilament 201 as it is directed through system 100.

In various embodiments of the present disclosure, nanostructures 401 may be produced at capital expenses up to 20× lower than a conventional reactor for synthesizing nanotubes. Moreover, system 100 may have a smaller physical footprint than present systems. Each of furnaces 300 and 400, in an embodiment, may be designed to be only about an inch in diameter and approximately one foot long. As described in the following section, such a design may provide for the synthesis of a plurality of nanostructures 401 within a limited space, as well as the manufacture of materials therefrom. It should be recognized that the size of system 100 and components thereof may vary depending on the particular application.

### System 600

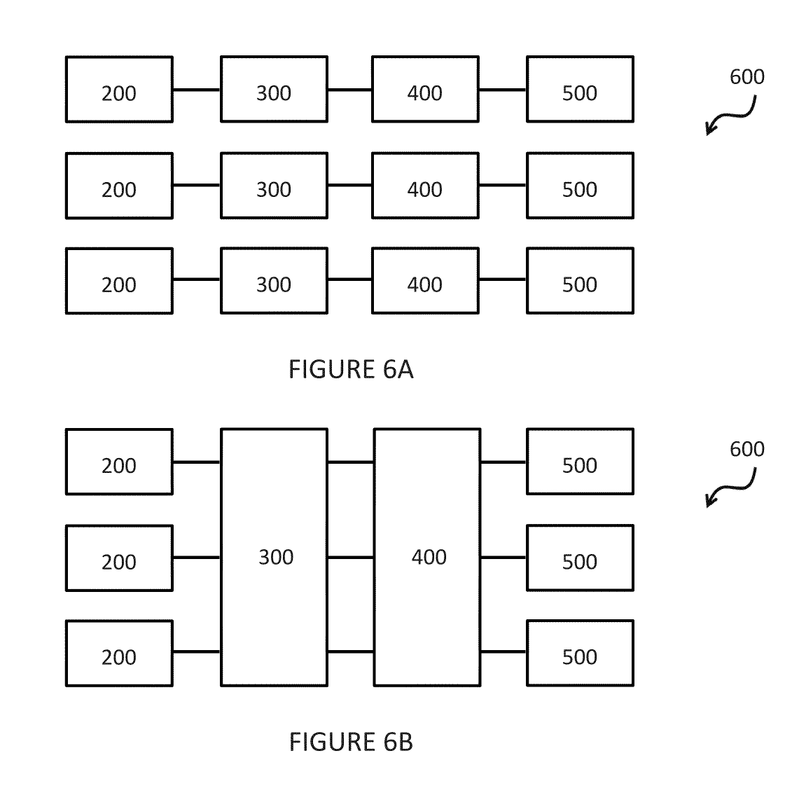

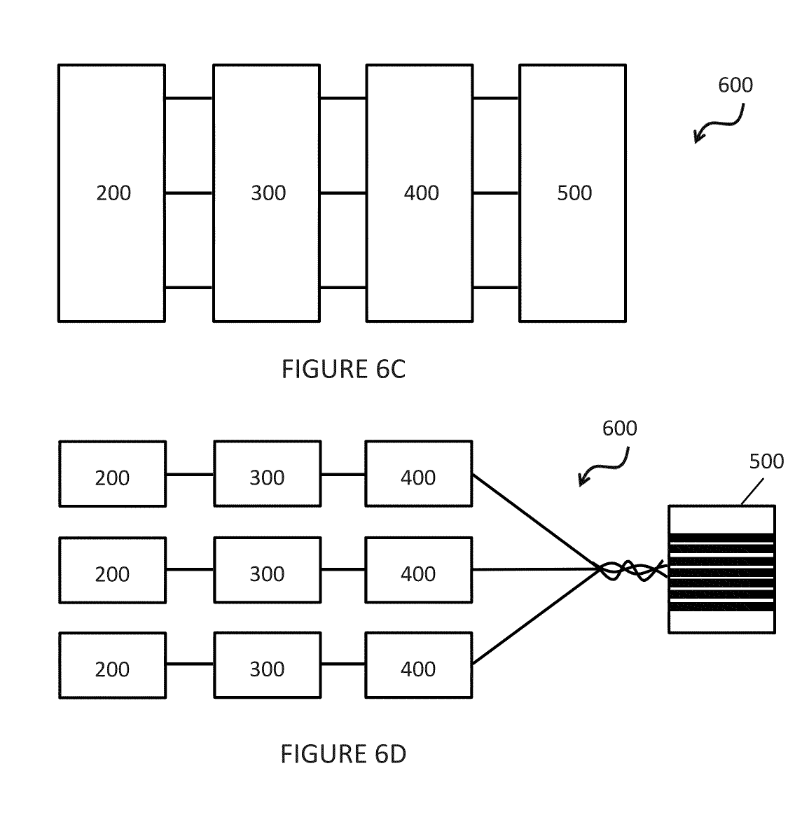

FIGS. 6A-6D illustrate representative configurations of system 600 and parts thereof. It should be understood that the components of system 600 shown in FIGS. 6A-6D are for illustrative purposes only, and that any other suitable components or subcomponents may be used in conjunction with or in lieu of the components comprising system 600 described herein.

Embodiments of system 600 may be used in connection with the synthesis of a plurality of extended length nanostructures, as well as the synthesis of materials formed from a plurality of extended length nanostructures, amongst other possible uses.

Various embodiments of system 600 are depicted in FIGS. 6A-6D. Generally speaking, system 600 may generally include an array of multiple systems 100 for producing a plurality of nanostructures. As shown in FIG. 6A, system 600 may include a plurality of separate systems 100, each including its own nanotube distributor 200, furnace 300, furnace 400, and collector 500. However, in various embodiments, one or more of these components may be shared across all or a portion of system 600. For example, referring to FIG. 6B, an embodiment of system 600 may include shared furnaces 300 and 400. In another embodiment, all components 200, 300, 400 and 500 may be shared across system 600, as shown in FIG. 6C. It should be recognized that these embodiments depict only a few possible combinations, and that system 600 may include any suitable number of combinations, the number of which may depend in part on the number of nanofilaments 201 to be directed through the system.

Embodiments of system 600 provide for the synthesis of a volume of substantially uniform nanostructures. The dimensions of each nanostructure produced, such as diameter and length, may be highly uniform as all formation aspects may be highly controlled within tight, consistent tolerances applied across the system. For example, unlike the liquid metal droplets that serve as catalyst particles in CVD synthesis, which can vary in diameter from a few nanometers to tens of nanometers, the diameter of nanofilaments 201 on which nanostructures 401 are formed can be controlled within tolerances of several nanometers (e.g., ±3 nm). Nanostructures 401 formed thereon may have a similar inner diameter as the outer diameter of a corresponding nanofilament 201 by virtue of the described formation method. Further, because diameter directly affects nanostructure properties such as chirality, electrical conductivity/resistance, and thermal conductivity/resistance, these properties may also be highly controlled across the plurality of nanostructures 401 being synthesized in system 600. Similarly, system 600 provides for the synthesis of a plurality of nanostructures 401 having uniform thicknesses, constructions, and lengths at least because residence time may be consistently and precisely controlled across system 600. That is, each nanofilament 201 may move at the same speed, and be exposed to the same temperatures and the same amount of coating source at precisely the same point in the formation process. Traditional CVD systems may lack this level of precision, at least in part because: a) catalyst size may not be controlled to the same level of precision without the use of sophisticated techniques; and b) the catalysts may float freely or may be spread out within a reactor, thereby subjecting them to varying local temperatures and varying concentrations of conditioning compound and carbon source. System 100 may similarly produce volume of substantially uniform nanostructures, albeit in a slower, one-after-another fashion, as compared to the mass production potential provided by the ability of system 600 to produce a plurality of uniform nanostructures in parallel.

Referring now to FIG. 6D, embodiments of system 600 may further provide for the production of nanomaterials from nanostructures 401 as they are synthesized. In various embodiments, system 600 may include a collector 500 configured to simultaneously collect and organize a plurality of the nanostructures 401 into a nanomaterial. In the embodiment shown, collector 500 may be configured to twist a plurality of nanostructures 401 into a yarn as they collected according to methods known in the art. In another embodiment, collector 500 may be configured to simultaneously pick up a plurality of nanostructures 401 using an adhesive strip similar to a “post-it” note, and to pull those nanofilaments onto a rotating belt to form a sheet or mat of nanostructures 401. Notably, these nanomaterials, being formed from extended length nanostructures, may have greater mechanical strength and electrical/thermal conductivity than those formed from an aggregate of smaller nanotubes.

System 600, in an embodiment, may be further configured to produce nanostructures 401 of having selectively varying properties so as to form a hybrid nanomaterial. For example, if system 600 were to produce nanostructures of diameter A near the center of the array, and nanostructures of diameter B near the peripheries of the array, subsequent collection may provide a nanomaterial having properties associated with diameter A at its core, and properties associated with diameter B at its periphery. In an embodiment, such an arrangement could be used to produce a nanofibrous yarn having a low conductivity core and a high conductivity outer surface. It should be recognized that this is just one of many possible arrangements, and that system 600 may be configured to produce any number of hybrid nanomaterials in a related fashion.

### Operation

In operation, nanofilament 201 of system 100 (or an array thereof in the case of system 600), may be continuously dispensed from nanofilament distributor 200 and directed through various stages of these systems while serving as a supports on which nanostructures 401 may be formed.

Nanofilament 201 may be initially directed through furnace 300 for the first stage of nanofilament formation. In one embodiment, nanofilament 201 may first be heated by heater 310 to a temperature range T₁. Next, the heated nanofilament may be directed downstream to a location within furnace 300 in which it may be coated with source material 321, such as a carbonaceous gas. Upon contact with the heated nanofilament 201, source material 321 may decompose into its constituent atoms to form a non-ordered layer of nanostructure precursor 301, such as solid carbon, on the surface of nanofilament 201. It should be recognized that, in another embodiment, nanofilament 201 may first be coated with source material 321 and subsequently heated to form a layer of nanostructure precursor 301 on the surface of nanofilament 201.

Nanofilament 201 coated with nanostructure precursor 301 may then be directed through furnace 400 for the next stage of nanofilament formation. In an embodiment, the coating of nanostructure precursor 301 may be heated by heater 410 to a temperature range T₂. At such temperatures, the relatively disordered atomic structure of nanostructure precursor 301 may be rearranged to form nanostructure 401 having an ordered structure resembling that of conventional nanotube structures. If nanofilament 201 is still present after nanostructure 401 is formed, the combination may continue to be heated, possibly at higher temperatures, until nanofilament 201 is decomposed and removed. The resulting hollow nanostructure may then be directed onto collector 500 for harvesting.

To ensure that the decomposition of nanofilament 201 does not preclude subsequent portions of nanofilament 201 from being pulled through previous stages of system 100, in one embodiment, residence time within furnace 400 may be limited initially to allow a portion of nanofilament 201 to pass through intact, and thereby serve as a lead to pull upstream portions. The speed at which nanofilament 201 is directed through the system may then be decreased (i.e., residence time increased) so as to allow nanostructure 401 to form within furnace 400 from the coating of nanostructure precursor 301. When exposure sufficient to decompose nanofilament 201, a portion of nanostructure 401 surrounding the area of decomposition may form a bridge between the surviving downstream nanofilament lead and the intact upstream portion of nanofilament 201. As the initial lead is collected on collector 500, it may continue to pull upstream portions of nanofilament 201 via the portion of nanostructure 401 bridging the break. Any portion of nanofilament 201 not fully decomposed may be completely decomposed and removed as nanofilament 201 is directed through the remainder of furnace 400. Similarly, rather than varying residence time, the temperature within furnace 400 may be varied to achieve the same effects. To the extent desired, the initially collected portion (i.e., lead) of nanofilament 201 may be sacrificed such that the remaining harvest includes only nanostructure 401.

The production of extended length nanotubes and other nanostructures enables applications that utilize their extraordinary mechanical and electronic properties. The nanotubes and nanostructures produced by the systems and methods of the present invention can be woven or assembled into a fibrous material and treated for use in connection with various applications, including heat sinks, electric power transmission lines which require strength and conductivity, electric motor and solenoid windings which require low resistivity and minimum eddy current loss, high strength fiber-reinforced composites including carbon-carbon and carbon-epoxy, lightning protection, emi shielding, and flame proofing materials, and nanotube-based cables, fibers, tows, textiles, and fabrics. Also included are devices made from these nanotubes and nanostructures such as heaters, de-icers, thermoelectric generators, adapters, batteries, antennae, sporting goods products, lightning protection devices, and insulators, as well as textiles such as armor of various types, protective clothing, energy-generating tethers and the like. The present invention also contemplates coating individual nanotubes or groups of nanotubes with either a thermoset epoxy or a high-carbon polymer, such as furfuryl alcohol or RESOL to act as a composite precursor.

While the present invention has been described with reference to certain embodiments thereof, it should be understood by those skilled in the art that various changes may be made and equivalents may be substituted without departing from the true spirit and scope of the invention. In addition, many modifications may be made to adapt to a particular situation, indication, material and composition of matter, process step or steps, without departing from the spirit and scope of the present invention. All such modifications are intended to be within the scope of the claims appended hereto.

What is claimed is:

1. A system for synthesis of extended length nanostructures, the system comprising:
a nanofilament acting as a support on which an extended length nanostructure may be formed;
a first furnace, through which the nanofilament is directed, and within which: a) a source material for forming a nanostructure is deposited circumferentially around the nanofilament, and b) the source material is decomposed into its constituent atoms to form a surface layer of nanostructure precursor coating the nanofilament; and
a second furnace within which the coated nanofilament is exposed to a temperature range higher than that in the first furnace to rearrange the atomic structure of the surface layer to form the nanostructure.

2. A system as set forth in claim 1, wherein the nanofilament includes a material made from one of magnesium oxide, zinc oxide, indium tin oxide, boron nitride, and a high temperature polymer.

3. A system as set forth in claim 1, wherein the nanofilament has a diameter up to 100 nanometers.

4. A system as set forth in claim 1, wherein the first furnace is configured to heat the nanofilament to a first temperature range sufficient to decompose the source material into the nanostructure precursor upon contact with the heated nanofilament.

5. A system as set forth in claim 1, wherein the first furnace is configured to heat the nanofilament to between 500° C. and 1500° C.

6. A system as set forth in claim 1, wherein the source material includes one of a purely carbonaceous material, an oxygen-containing carbonaceous material, a sulfur-containing carbonaceous material, a hydrocarbon compound, and a boron-containing compound.

7. A system as set forth in claim 1, wherein the temperature range of the second furnace is between 1500° C. and 3000° C.

8. A system as set forth in claim 1, wherein the temperature range of the second furnace is sufficient to remove secondary materials from the coating.

9. A system as set forth in claim 1, wherein the temperature range of the second furnace is sufficient to decompose the nanofilament on which the nanostructure is formed.

10. A system as set forth in claim 1, wherein the nanostructure is synthesized circumferentially about the nanofilament.

11. A system as set forth in claim 1, wherein the entirety of the nanostructure is synthesized about the nanofilament.

12. A system as set forth in claim 1, wherein the nanostructure approximates the shape and size of the nanofilament.

13. A system as set forth in claim 1, wherein the nanostructure is free of residual catalyst.

14. A system as set forth in claim 1, further including a nanofilament distributor from which the nanofilament may be directed.

15. A system as set forth in claim 14, wherein the nanofilament distributor includes a nanofilament formation device for synthesizing the nanofilament from a nanofilament precursor material.

16. A system as set forth in claim 15, wherein the nanofilament formation device utilizes one of an electrospinning process or a pyroelectrodynamic shooting process to form the nanofilament.

17. A system as set forth in claim 1, further including a collector downstream of the second furnace for collecting the nanostructure.

18. A system for synthesis of a plurality of extended length nanostructures, the system comprising:
an array of nanofilaments for serving as supports on which a plurality of nanostructures may be formed;
a first zone through which the nanofilaments are directed, and within which a layer of precursor material from which a nanostructure may be formed is applied to a surface of each nanofilament, and;
a second zone, situated downstream from the first zone, within which the nanofilaments are exposed to a temperature range to rearrange the atomic structure of the corresponding precursor surface layers thereon to form the plurality of nanostructures.

19. A system as set forth in claim 18, wherein the array of nanofilaments is dispensed from one or more nanotube formation devices.

20. A system as set forth in claim 18, wherein the first zone includes one or more furnaces through which the nanofilaments are directed.

21. A system as set forth in claim 18, wherein, within the first zone, a source material is deposited onto the surface of each nanofilament and decomposed into its constituent atoms to form the layer of precursor material.

22. A system as set forth in claim 18, wherein the second zone includes one or more furnaces through which the nanofilaments are directed.

23. A system as set forth in claim 18, further including a collector downstream of the second zone for simultaneously collecting at least two of the plurality of nanostructures.

24. A system as set forth in claim 23, wherein the collector is configured to form a twisted yarn from the nanostructures during collection.

25. A system as set forth in claim 18, wherein each of the plurality of nanostructures have substantially uniform diameters.

26. A method for synthesizing a plurality of extended length nanostructures, the method comprising:
depositing, onto a nanofilament support, a source material for forming a nanostructure;
decomposing, at a first temperature range, the source material to form a surface layer of nanostructure precursor on the nanofilament; and
rearranging, at a second temperature range higher than the first temperature range, atomic structure of the nanostructure precursor surface layer on the nanofilament to form the nanostructure.

27. A method as set forth in claim 26, wherein, in the step of depositing, the source material includes one of a purely carbonaceous material, an oxygen-containing carbonaceous material, a sulfur-containing carbonaceous material, a hydrocarbon compound, and a boron-containing compound.

28. A method as set forth in claim 26, wherein the step of decomposing includes allowing constituent atoms of the decomposed source material to accumulate on the surface of the nanofilament to form the surface layer of nanostructure precursor.

29. A method as set forth in claim 26, wherein in the step of decomposing, the surface layer of nanostructure precursor has a disordered atomic structure.

30. A method as set forth in claim 26, wherein the first temperature range is between 500° C. and 1500° C.

31. A method as set forth in claim 26, wherein in the step of rearranging, the nanostructure has an ordered atomic structure.

32. A method as set forth in claim 26, wherein second temperature range is between 1500° C. and 3000° C.

33. A method as set forth in claim 26, further including the step of removing the nanofilament from within the nanostructure to form a nanostructure that is free of residual catalyst.

34. A method as set forth in claim 26, wherein a plurality of substantially uniform diameter nanofilaments are provided for serving as supports on which a corresponding number of substantially uniform diameter nanostructures may be formed.
